(19) United States
(12) Patent Application Publication
(10) Pub. No.: US 2016/0141217 A1
(43) Pub. Date: May 19, 2016

(54) ELECTRONIC PACKAGE AND FABRICATION METHOD THEREOF

(71) Applicant: Siliconware Precision Industries Co., Ltd., Taichung (TW)

(72) Inventors: Pei-Lin Chen, Taichung (TW); Lien-Chen Chiang, Taichung (TW)

(21) Appl. No.: 14/695,066

(22) Filed: Apr. 24, 2015

(30) Foreign Application Priority Data
Nov. 17, 2014 (TW) 103139709

(51) Int. Cl. H01L 23/31; H01L 25/065; H01L 23/498; H01L 21/78; H01L 21/56

(52) U.S. Cl. CPC H01L 23/3114; H01L 21/78; H01L 21/561; H01L 23/49838; H01L 25/0655

(57) ABSTRACT

A method for fabricating an electronic package, including the steps of: providing a substrate having a plurality of electronic elements and a plurality of separation portions formed between the electronic elements, wherein each of the electronic elements has an active surface with a plurality of electrode pads and an inactive surface opposite to the active surface; forming at least an opening in each of the separation portions from a side corresponding to the inactive surfaces of the electronic elements, wherein the at least an opening does not penetrate the separation portion; forming an encapsulant in the opening; and singulating the electronic elements along the opening from a side corresponding to the active surfaces of the electronic elements. As such, each of the electronic elements has a side surface adjacent to and connecting the active and inactive surfaces of the electronic element and the side surface is partially covered by the encapsulant for protection.

### BACKGROUND OF THE INVENTION

1. Field of the Invention

The present invention relates to packaging processes, and more particularly, to a chip scale package and a fabrication method thereof.

2. Description of Related Art

Chip scale packages have been developed to meet the miniaturization requirement of semiconductor packages and electronic products. The size of a chip scale package is substantially 1.2 times the size of a chip.

In addition to small size, a chip scale package needs high integration and high I/O count for electrically connecting with an external device such as a circuit board so as to meet the demands of electronic products for high performance and high processing speed. To increase the I/O count, as many electrode pads as possible are formed on an active surface of a chip. However, the number of the electrode pads is limited by the area of the active surface of the chip and the pitch between the electrode pads. To form as many I/O contacts as possible on a limited area, wafer-level chip scale packages are developed.

Generally, an RDL (Redistribution Layer) process is performed on a wafer-level chip scale package. The RDL process includes forming a plurality of conductive traces on an active surface of a wafer having a plurality of chips. One ends of the conductive traces are electrically connected to electrode pads of the chips and the other ends of the conductive traces serve as electrical contacts for mounting solder balls. Then, a singulating process is performed. As such, the wafer is cut into a plurality of chips each having a plurality of solder balls formed on the active surface thereof.

In the above-described singulating process, a diamond cutter is generally used to cut the wafer from the active surface thereof. However, during this process, the side and active surfaces of the chips are easily damaged by the diamond cutter due to such as stresses or sideway impacts. Further, since the side and inactive surfaces of the chips are exposed to external environment after the singulating process, the chips easily crack during picking and placing operations.

Therefore, there is a need to provide an electronic package and a fabrication method thereof so as to overcome the above-described drawbacks.

### SUMMARY OF THE INVENTION

In view of the above-described drawbacks, the present invention provides a method for fabricating an electronic package, which comprises the steps of: providing a substrate having a plurality of electronic elements and a plurality of separation portions formed between the electronic elements, wherein each of the electronic elements has an active surface with a plurality of electrode pads and an inactive surface opposite to the active surface; forming at least an opening in each of the separation portions from a side corresponding to the inactive surfaces of the electronic elements, wherein the opening does not penetrate the separation portion; forming an encapsulant in the openings; and singulating the electronic elements along the openings from a side corresponding to the active surfaces of the electronic elements so as to allow each of the electronic elements to have a side surface adjacent to and connecting the active and inactive surfaces of the electronic element and partially covered by the encapsulant.

In the above-described method, the singulating process can comprise laser cutting the separation portions first and then cutting the encapsulant in the openings with a diamond cutter.

In the above-described method, each of the singulating paths of the singulating process can be less in width than each of the separation portions.

In the above-described method, if each of the separation portions has a plurality of openings formed therein, the singulating path can be positioned between the openings.

In the above-described method, if each of the separation portions has a single opening formed therein, the singulating path can correspond in position to the opening.

In the above-described method, the portion of the electronic package covered by the encapsulant can have a thickness of at least 20 um.

The present invention further provides an electronic package, which comprises: an electronic element having an active surface with a plurality of electrode pads, an inactive surface opposite to the active surface, and a side surface adjacent to and connecting the active and inactive surfaces; and an encapsulant covering the side surface of the electronic element, wherein the portion of the electronic package covered by the encapsulant has a thickness of at least 20 um.

In the above-described package and method, the electronic package can have a thickness of 45 to 787 um.

In the above-described package and method, the encapsulant can further be formed on the inactive surface of the electronic element.

In the above-described package and method, an RDL structure can be formed on the active surface of the electronic element and electrically connected to the electrode pads of the electronic element.

In the above-described package and method, a plurality of electronic elements can be formed on the active surface of the electronic element and electrically connected to the electrode pads of the electronic element.

In the above-described package and method, the singulated electronic element can be bonded to a packaging substrate via the active surface thereof.

Therefore, the present invention mainly involves forming openings in the separation portions from a side corresponding to the inactive surfaces of the electronic elements and then singulating the electronic elements along the openings from a side corresponding to the active surfaces of the electronic elements. As such, the side and inactive surfaces of the singulated electronic elements can be covered by the encapsulant so as to prevent the electronic elements from being damaged in subsequent processes such as picking and placing operations, thereby improving the product yield.

### BRIEF DESCRIPTION OF DRAWINGS

FIGS. 1A to 1H are schematic cross-sectional views showing a method for fabricating an electronic package according to the present invention, wherein FIGS. 1B′, 1C′, 1D′ and 1H′ show other embodiments of FIGS. 1B, 1C, 1D and 1H, respectively; and

FIGS. 2A to 2C are schematic cross-sectional views showing different embodiments of the electronic package of the present invention.

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modifications and variations can be made without departing from the spirit of the present invention. Further, terms such as “on”, “a” etc. are merely for illustrative purposes and should not be construed to limit the scope of the present invention.

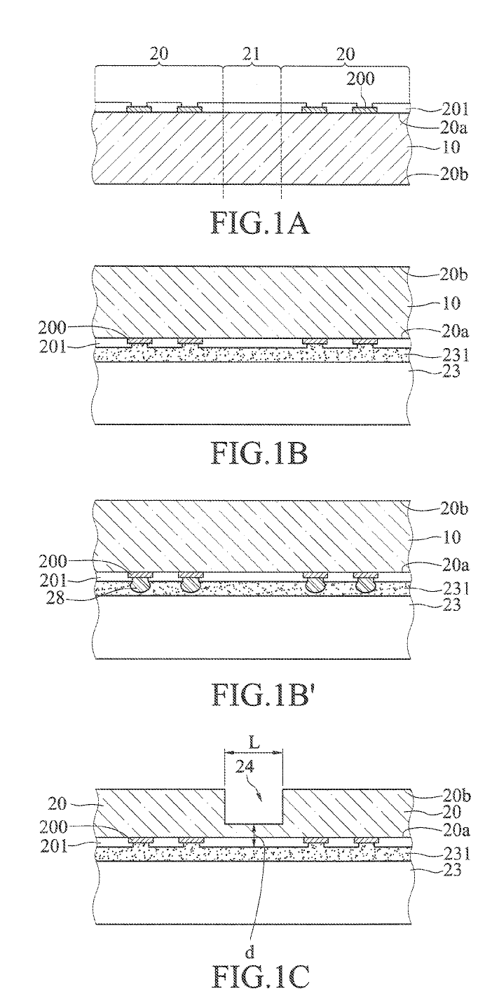

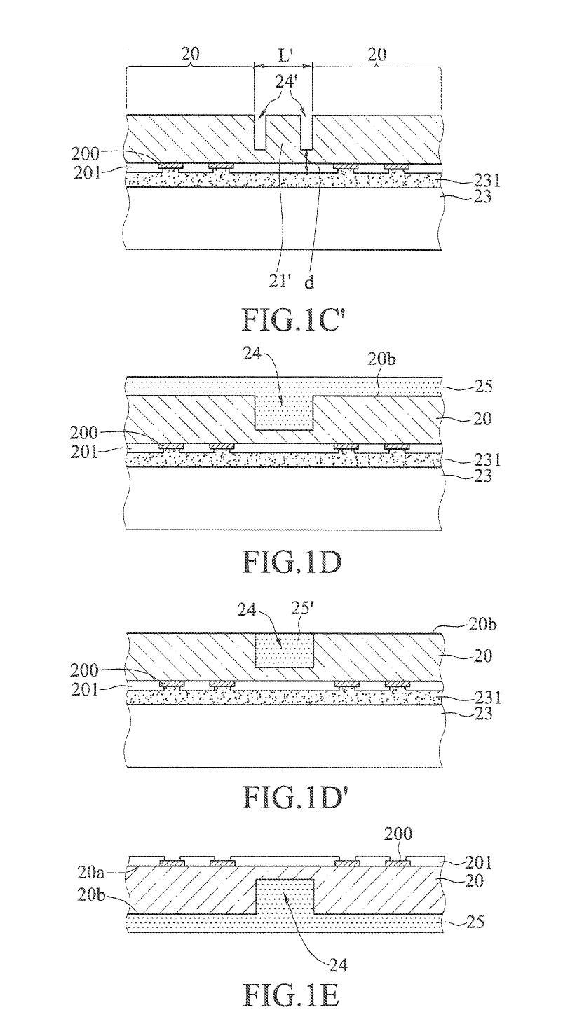

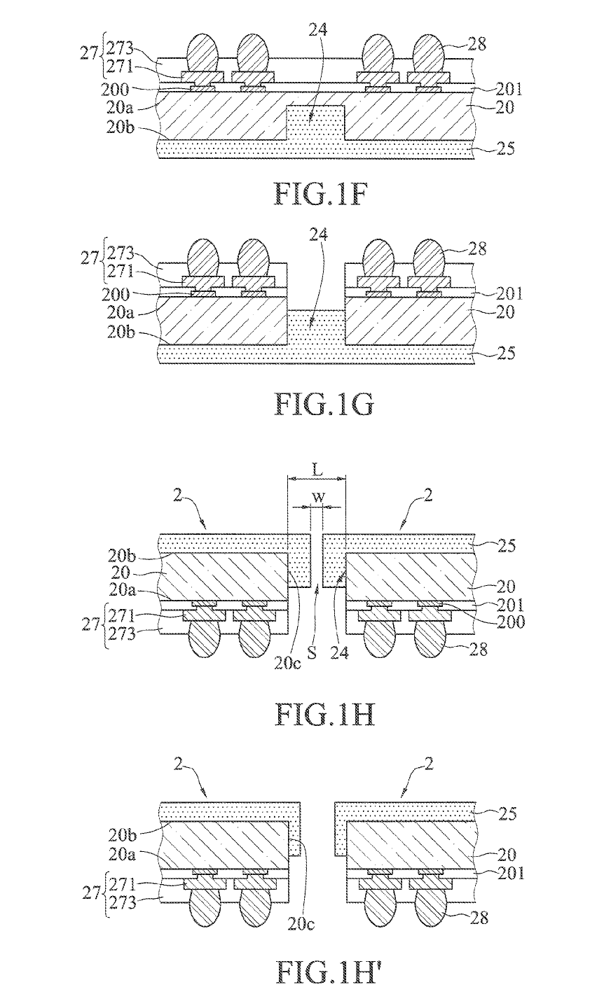

FIGS. 1A to 1H are schematic cross-sectional views showing a method for fabricating an electronic package 2 according to the present invention.

Referring to FIG. 1A, a substrate 10 is provided, which has a plurality of electronic elements 20 and a plurality of separation portions 21 formed between the electronic elements 20.

In the present embodiment, each of the electronic elements 20 has an active surface 20a with a plurality of electrode pads 200 and an inactive surface 20b opposite to the active surface 20a. Further, a passivation layer 201 is formed on the active surfaces 20a of the electronic elements 20 and exposing the electrode pads 200 of the electronic elements 20.

Each of the electronic elements 20 is an active element such as a semiconductor chip, or a passive element such as a resistor, a capacitor or an inductor. In the present embodiment, the substrate 10 is a silicon wafer, and the electronic elements 20 are chips.

Referring to FIG. 1B, a carrier 23 is disposed on the passivation layer 201. In the present embodiment, a release layer 231 is formed between the passivation layer 201 and the carrier 23 to facilitate subsequent delamination of the carrier 23 and prevent damage of the electronic elements 20.

Referring to FIG. 1C, the separation portions 21 are cut by using such as a diamond cutter from a side corresponding to the inactive surfaces 20b of the electronic elements 20 so as to form an opening 24 in each of the separation portions 21. The opening 24 does not penetrate the separate portion 21.

In the present embodiment, each of the separation portions 21 is partially removed and the remaining portion has a thickness d of about 20 um. The width L of the opening 24, i,e, the width of the separation portion 21, is in a range of 10 um to 3 mm. Further, a thinning process can be selectively performed on the inactive surfaces 20b of the electronic elements 20.

In another embodiment, referring to FIG. 1C′, a plurality of openings 24′ are formed in each of the separation portions 21. The total width L′ of the openings 24′ and the remaining separation portion 21′, i.e., the width of the separation portion 21, is in a range of 15 um to 4 mm.

Referring to FIG. 1D, continued from FIG. 1C, an encapsulant 25 is formed in the openings 24 of the separation portions 21 and on the inactive surfaces 20b of the electronic elements 20 so as to cover side and inactive surfaces of the electronic elements 20.

In the present embodiment, the encapsulant 25 is filled in the openings 24 and hence formed around peripheries of the electronic elements 20. The encapsulant 25 is made of an insulating material, for example, a molding compound material, a dry film material, a photoresist material or a solder mask material.

In another embodiment, referring to FIG. 1D′, an encapsulant 25′ is formed in the openings 24 of the separation portions 21 and does not cover the inactive surfaces 20b of the electronic elements 20.

Referring to FIG. 1E, continued from FIG. 1D, the carrier 23 and the release layer 231 are removed to expose the electrode pads 200 of the electronic elements 20 and the passivation layer 201.

Referring to FIG. 1F, an RDL (Redistribution Layer) process is performed. As such, an RDL structure 27 is formed on the passivation layer 201 and electrically connected to the electrode pads 200 of the electronic elements 20. Then, a plurality of conductive elements 28 are formed on the RDL structure 27.

In the present embodiment, the RDL structure 27 has a circuit layer 271 formed on the passivation layer 201 and electrically connected to the electrode pads 200 of the electronic elements 20, and an insulating layer 273 formed on the circuit layer 271.

Further, portions of the circuit layer 271 are exposed from the insulating layer 273, and the conductive elements 28 are formed on the exposed portions of the circuit layer 271 and electrically connected to the circuit layer 271.

The conductive elements 28 are solder balls, metal bumps or a combination thereof.

In an embodiment, referring to FIG. 1B′, before the carrier 23 is disposed on the passivation layer 201, a plurality of conductive elements 28 are formed on the electrode pads 200 of the electronic elements 20. As such, when the carrier 23 is disposed on the passivation layer 201, the conductive elements 28 are embedded in the release layer 231 (or an adhesive layer). Therefore, the RDL structure 27 can be dispensed with.

Referring to FIGS. 1G and 1H, a singulating process is performed along the openings 24 from a side corresponding to the active surfaces 20a of the electronic elements 22 so as to separate the electronic elements 20 from one another. As such, a plurality of electronic packages 2 are obtained. Each of the singulated electronic elements 20 has a side surface 20c adjacent to and connecting the active and inactive surfaces 20a, 20b thereof.

In the present embodiment, the singulating process includes laser cutting the separation portions 21 first and then cutting the encapsulant 25 in the openings 24 with a diamond cutter.

The cutting paths S of the diamond cutter correspond in position to the openings 24 and the width W of the cutting paths S is less than the width L of the openings 24. As such, the encapsulant 25 covers the side surfaces 20c of the electronic elements 20. In another embodiment, both the separation portions 21 and the encapsulant 25 in the openings 24 are cut by using a diamond cutter.

Referring to FIG. 1H′, if the process is continued from FIG. 1C′, the cutting path is positioned between the openings 24′ of each of the separation portions 21, thereby obtaining a plurality of electronic packages 2.

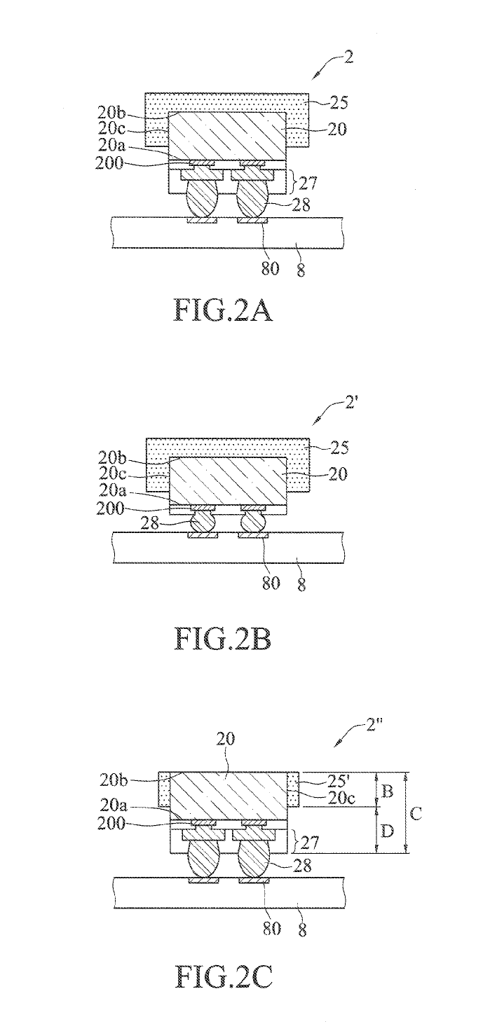

Subsequently, referring to FIG. 2A, such an electronic package 2 is bonded to conductive pads 80 of a packaging substrate 8 through the conductive elements 28. In another embodiment, referring to FIG. 2B, if the process is continued from FIG. 1B′, an electronic package 2′ is obtained. In a further embodiment, referring to FIG. 2C, if the process is continued from FIG. 1D′, an electronic package 2″ is obtained.

Referring to FIG. 2C, the thickness C of the electronic package 2″ (not including the conductive elements 28) is 45 to 787 um. At least a side surface of the electronic package 2″ has an exposed portion (not covered by the encapsulant 25) and a covered portion (covered by the encapsulant 25). The thickness D of the exposed portion is at least 25 um, and the thickness B of the covered portion is at least 20 um.

The present invention further provides an electronic package 2, 2′, 2″ which has: an electronic element 20 having an active surface 20a with a plurality of electrode pads 200, an inactive surface 20b opposite to the active surface 20a, and a side surface 20c adjacent to and connecting the active and inactive surfaces 20a, 20b; and an encapsulant 25, 25′ covering the side surface 20c of the electronic element 20, wherein the portion of the electronic package covered by the encapsulant has a thickness of at least 20 um.

In an embodiment, an RDL structure 27 is formed on the active surface 20a of the electronic element 20 and electrically connected to the electrode pads 200 of the electronic element 20.

In an embodiment, a plurality of electronic elements 28 are formed on the active surface 20a of the electronic element 20 and electrically connected to the electrode pads 200 of the electronic element 20.

In an embodiment, the encapsulant 25 is further formed on the inactive surface 20b of the electronic element 20.

In an embodiment, the electronic element 20 is bonded to a packaging substrate 8 via the active surface 20a thereof.

Therefore, the present invention mainly involves forming openings in the separation portions from a side corresponding to the inactive surfaces of the electronic elements and then singulating the electronic elements along the openings from a side corresponding to the active surfaces of the electronic elements. As such, the side and inactive surfaces of the singulated electronic elements can be covered by the encapsulant so as to prevent the electronic elements from being damaged in subsequent processes such as picking and placing operations, thereby improving the product yield.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A method for fabricating an electronic package, comprising the steps of:
providing a substrate having a plurality of electronic elements and a plurality of separation portions formed between the electronic elements, wherein each of the electronic elements has an active surface with a plurality of electrode pads and an inactive surface opposite to the active surface;
forming at least an opening in each of the separation portions from a side corresponding to the inactive surfaces of the electronic elements, wherein the opening does not penetrate the separation portion;
forming an encapsulant in each of the openings; and
singulating the electronic elements along the opening from a side corresponding to the active surfaces of the electronic elements so as to allow each of the electronic elements to have a side surface adjacent to and connecting the active and inactive surfaces of the electronic element and covered by the encapsulant.

2. The method of claim 1, wherein the singulating process comprises laser cutting the separation portions first and then cutting the encapsulant in the openings with a diamond cutter.

3. The method of claim 1, wherein each of singulating paths of the singulating process is less in width than each of the separation portions.

4. The method of claim 3, wherein if each of the separation portions has a plurality of openings formed therein, the singulating path is positioned between the openings.

5. The method of claim 3, wherein if each of the separation portions has a single opening formed therein, the singulating path corresponds in position to the opening.

6. The method of claim 1, wherein the encapsulant is further formed on the inactive surfaces of the electronic elements.

7. The method of claim 1, wherein the portion of the electronic package covered by the encapsulant has a thickness of at least 20 um.

8. The method of claim 1, wherein the electronic package has a thickness of 45 to 787 um.

9. The method of claim 1, further comprising forming on the active surfaces of the electronic elements an RDL (Redistribution Layer) structure that is electrically connected to the electrode pads of the electronic elements.

10. The method of claim 1, further comprising forming on the active surfaces of the electronic elements a plurality of conductive elements that are electrically connected to the electrode pads of the electronic elements.

11. The method of claim 1, after singulating the electronic elements, further comprising bonding each of the electronic elements to a packaging substrate via the active surface thereof.

12. An electronic package, comprising:
an electronic element having an active surface with a plurality of electrode pads, an inactive surface opposite to the active surface, and a side surface adjacent to and connecting the active and inactive surfaces; and
an encapsulant covering the side surface of the electronic element, wherein the portion of the electronic package covered by the encapsulant has a thickness of at least 20 um.

13. The package of claim 12, wherein the electronic package has a thickness of 45 to 787 um.

14. The package of claim 12, wherein the encapsulant is further formed on the inactive surface of the electronic element.

15. The package of claim 12, further comprising an RDL structure formed on the active surface of the electronic element and electrically connected to the electrode pads of the electronic element.

16. The package of claim 12, further comprising a plurality of electronic elements formed on the active surface of the electronic element and electrically connected to the electrode pads of the electronic element.

17. The package of claim 12, wherein the electronic element is bonded to a packaging substrate via the active surface thereof.
